(19) United States
(12) Patent Application Publication
(10) Pub. No.: US 2006/0244541 A1
(43) Pub. Date: Nov. 2, 2006

(54) Methods and apparatus for precision limiting in transimpedance amplifiers

(76) Inventor: Dejan Mijuskovic, Chandler, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/118,282

(22) Filed: Apr. 28, 2005

(51) Int. Cl. H03F 3/08

(52) U.S. Cl. 330/308

(57) ABSTRACT

A transimpedance amplifier is provided including an input, an amplifier and a non-linear limiting circuit. The input is configured to provide an input current which includes a logic high range between a minimum input current and a maximum input current for logic high. The input current also includes a range of knee values. The amplifier is configured to generate an output voltage having a range between a first voltage and a second voltage. The non-linear limiting circuit includes a first current source, a first diode connected transistor, a second diode connected transistor, and a second current source. The first diode connected transistor is prebiased to generate a first base-to-emitter voltage when the input current is approximately zero. The first diode connected transistor is configured to begin limiting the range of the output voltage at a selected knee value, which is slightly greater than the minimum input current for logic high, by changing the first base-to-emitter voltage when the input current reaches the selected knee value of the input current.

### TECHNICAL FIELD

The present invention generally relates to optical communications, and more particularly relates to transimpedance amplifiers.

### BACKGROUND

Optical networks use light signals to transmit data over a network. Although light signals are used to carry data, the light signals are typically converted into electrical signals in order to extract and process the data. The conversion of an optical signal into an electrical signal is often achieved utilizing an optical receiver. An optical receiver converts the optical signal received over the optical fiber into an electrical signal, amplifies the electrical signal, and converts the electrical signal into a digital data stream.

Burst-mode Passive Optical Networks (BPON) are widely used in the cable industry for transmission of optical light signals from an optical transmitter at a home to an optical module located at the hub/curb. Typical optical light signals used in BPON applications can have a frequency of a 155 mbps or greater. The use of burst-mode techniques requires fast and accurate handling of the incoming light signals and accurate handling of the optical power levels both on the transmitter and the receiver sides. An optical module typically includes an optical receiver that includes photodiode and a transimpedance amplifier. The transimpedance amplifier amplifies an input current signal from a photodiode into a relatively large amplitude output voltage signal.

FIG. 1 is a circuit diagram of a conventional optical receiver module which includes a transimpedance amplifier 1 and a photodiode (PD) 2. The transimpedance amplifier 1 converts an input current (Iin) into an output voltage (Vout). The transimpedance amplifier 1 comprises a feedback resistor (Rf) 6, a high gain voltage amplifier 8 and a non-linear limiting circuit 9.

The transimpedance amplifier 1 in conjunction with PD can successfully receive and amplify light signals which fall within a particular power range. Some of the existing standards require that the transimpedance amplifier 1 can detect an incoming optical light signal transmitted from distances up to 20 km away and having an optical power of −33 dBm. To accommodate such a wide range of optical signals, the transimpedance amplifier 1 should be able to detect and amplify very low levels and high levels of currents. The range of signals that can be successfully amplified is therefore effectively limited by the incident optical power of the light signal. The optical receiver might distort signals whose current is too large and might not recognize signals whose current is too low. It is desirable to provide a transimpedance amplifier having increased range of input currents.

The photodiode (PD) 2 is typically located outside a chip. The photodiode (PD) 2 has a diode capacitance associated with it which represents the parasitic capacitance between the photodiode (PD) 2 and other components in a chip such as pins and pads from node B to ground. A cathode of the photodiode (PD) 2 is biased via the amplifier 8. Node B couples the photodiode (PD) 2 to the feedback resistor (Rf) 6 and the voltage amplifier 8. The photodiode (PD) 2, coupled between ground and node B, detects an incoming optical light signal of sufficient strength and converts the light signal into an input current (Iin) which flows from the voltage amplifier 8. The light signals received by the transimpedance amplifier 1 can vary significantly in both amplitude and power. The signal current is often related, for example, to the length of the optical fiber over which the light signal was transmitted, the power of the transmitting laser source, the efficiency of the photodiode (PD), etc. These and other factors result in input currents to the transimpedance amplifier which can vary significantly. Because the current (Iin) generated by the photodiode (PD) 2 is approximately proportional to the light which impinges on the cathode of the photodiode (PD) 2, in some cases the input signal (Iin) can be weak and in other cases it can be stronger.

In BPON applications, the transimpedance amplifier 1 is preferably designed to handle a variation of nearly 1000:1 in the amplitude of the input current signal (In). Transimpedance amplifiers used in BPON type applications are required to work properly, for example, with a range of input currents (Iin) from 375 nA to 320 μA. In one implementation, light impinging on the photodiode (PD) 2 which generates an input current flow (Iin) between 375 nA to 320 μA corresponds to a logic 1. By contrast, light impinging on the photodiode (PD) 2 which generates an input current (Iin) of not more than one-tenth of logic 1 current is interpreted as a logic 0. In other words, the input current (Iin) of 375 nA to 320 μA (which corresponds to a logic 1) is at least ten times greater than the input current flow (Iin) which corresponds to a logic 0.

The voltage amplifier 8 is coupled between node B and node C and in parallel with the feedback resistor (Rf) 6. The voltage amplifier 8 can be a large gain amplifier in which the gain (−A) ranges from 100 to 1000 or more. The voltage amplifier 8 also has relatively large input impedance on the order of 100 kOhm. The voltage amplifier 8 generates an output voltage (Vout) at node C. For small input currents when diode-connected transistor (Q4) does not conduct, the magnitude of the output voltage (Vout) is approximately equal to the product of the input current (Iin) and the value of the feedback resistor (Rf) 6. The output voltage (Vout) can then be converted into a digital data stream for use by successive circuits coupled to the transimpedance amplifier 1.

The feedback resistor (Rf) 6 coupled in parallel across an input terminal (node B) at node A and output terminal (node C) at node D of the voltage amplifier 8. The feedback resistor (Rf) 6 can be made of a tungsten or a polysilicon layer, for example. The feedback resistor (Rf) 6 carries a current to the voltage amplifier 8. The input current (Iin) flows from node C to node B substantially through the feedback resistor (Rf) 6 because of the high input impedance of the voltage amplifier 8. When the photodiode (PD) 2 draws the input current (Iin) which is small such that diode-connected transistor (Q4) does not conduct, the output voltage (Vout) at the feedback resistor (Rf) 6 lowers such that feedback resistor (Rf) 6 provides the input current (Iin).

It is desirable to minimize or reduce noise in the circuit so that the signal-to-noise ratio (SNR) is not too low for weak input currents (Iin). To achieve greater gain and sensitivity the value of the feedback resistor (Rf) 6 is typically increased. Increasing the value of the feedback resistor (Rf) 6 helps increase the signal-to-noise ratio (SNR) since the output signal (Vout) increases proportionally to the increase in the value of feedback resistor (Rf) 6. By contrast, the noise generated by feedback resistor (Rf) 6 increases proportionally to the square root of the value of the feedback resistor (Rf) 6. Thus, the feedback resistor (Rf) 6 helps improve the signal-to-noise ratio (SNR) by an amount approximately equal to the square root of the value of the feedback resistor (Rf) 6. In one implementation, the feedback resistor (Rf) is approximately 80 kOhm.

To achieve operation with a large input current (Iin), a non-linear limiting circuit 9 is typically connected in parallel with the feedback resistor (Rf). The impedance of this non-linear limiting circuit decreases with an increased input current (Iin), thus limiting the swing or “dynamic range” of the output voltage (Vout).

In FIG. 1 the limiting circuit 9 consists of a diode-connected transistor (Q0) 4 coupled in parallel with the feedback resistor (Rf) between nodes A and D. The diode-connected transistor (Q0) 4 helps limit the amplitude of the input current (Iin) by providing a non-linear transimpedance. The output voltage (Vout) swing is approximately equal to the base-to-emitter voltage (Vbe) of the diode-connected transistor (Q0) 4. When maximum input current (In) is applied, the swing of the output voltage (Vout) can be as high as 1V since the output voltage (Vout) changes from approximately 2*Vbe to 3*Vbe.

When the input current (Iin) is small, it is desirable to increase the SNR by applying a larger voltage gain to the output voltage (Vout). However, a swing of 1V limits the amount of additional voltage gain that can be applied to the output voltage (Vout). The additional voltage gain that can be applied to the output voltage (Vout) is desirable, since this can reduce the influence of circuits which are coupled to the output of the transimpedance amplifier 1 on the SNR.

FIG. 2 is a circuit diagram of another conventional optical receiver module 11 which includes a transimpedance amplifier 10 and a photodiode (PD) 2. The transimpedance amplifier 10 includes a large gain voltage amplifier 8, a feedback resistor (Rf) 6 and a limiting circuit 19. The photodiode (PD) 2 is coupled between ground and node B, the large gain voltage amplifier 8 is coupled between node B and C, the feedback resistor (Rf) 6 is coupled to nodes A and D in parallel with the large gain voltage amplifier 8, and the limiting circuit 19 is coupled between nodes A and D in parallel with the feedback resistor (Rf) 6.

The limiting circuit 19 includes a diode-connected transistor (Q0) 4 coupled between nodes A and E, a first current source (I0) 5 coupled between a supply voltage (Vcc) and node E, and a resistor (R1) 7 coupled between nodes E and D. The first current source 5 generates a current (I0).

This configuration of the transimpedance amplifier 10 achieves slight improvement with respect to the swing of the output voltage (Vout) by providing initial bias to diode-connected transistor (Q0) 4 which can result in an output voltage (Vout) swing of V_{be4}−I0*R1. However, temperature variations of the terms V_{be4} and I0*R1 are not meaningfully related to each other. The term I0*R1 is limited to small value so that diode-connected transistor (Q0) 4 does not turn on too quickly. An unacceptable SNR penalty follows if the transimpedance is reduced while the input current (In) is at its minimum level. As such, the achievable reduction in the swing of the output voltage (Vout) is small.

When input current (Iin) increases to 375 nA (from logic zero to logic one), the output voltage (Vout) of the transimpedance amplifier 1 changes from its self-bias point of (changed Vbe4 into Vbe) approximately 2*V_{be} to an output voltage (Vout) of 2*V_{be}+Rf*Iin. When the feedback resistor (Rf) has a relatively large value, such as 80 kOhm for example, this change is 30 mV. However, when maximum input current (Iin) of 320 μA is applied, the output voltage (Vout) of the transimpedance amplifier 1 changes by Vbe0−Rf*I0. This represents only a small improvement compared with FIG. 1, since the term Rf*I0, as already stated is small, for example 0.2V. Hence, the swing at Vout is about 0.8V.

Thus, it is desirable to provide a transimpedance amplifier which has increased range of input currents so that it can detect and amplify very low levels and high levels of optical power (e.g., −33 dBm or greater) at photodiode (PD) 2. It also is desirable to provide a transimpedance amplifier in which the swing of the output voltage (Vout) can be limited to allow for a larger voltage gain to be applied to the output voltage (Vout) so that the signal-to-noise ratio (SNR) of the output voltage (Vout) is not too low. For instance, it would be desirable to provide a transimpedance amplifier having a precise limiting mechanism which can reduce swing of output voltage (Vout) at maximum input current (Iin) to allow a higher additional gain to be applied to the output voltage (Vout). Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIG. 1 is a circuit diagram of a conventional transimpedance amplifier;

FIG. 2 is a circuit diagram of another conventional transimpedance amplifier; and

FIG. 3 is a circuit diagram of a transimpedance amplifier according to an exemplary embodiment.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element.

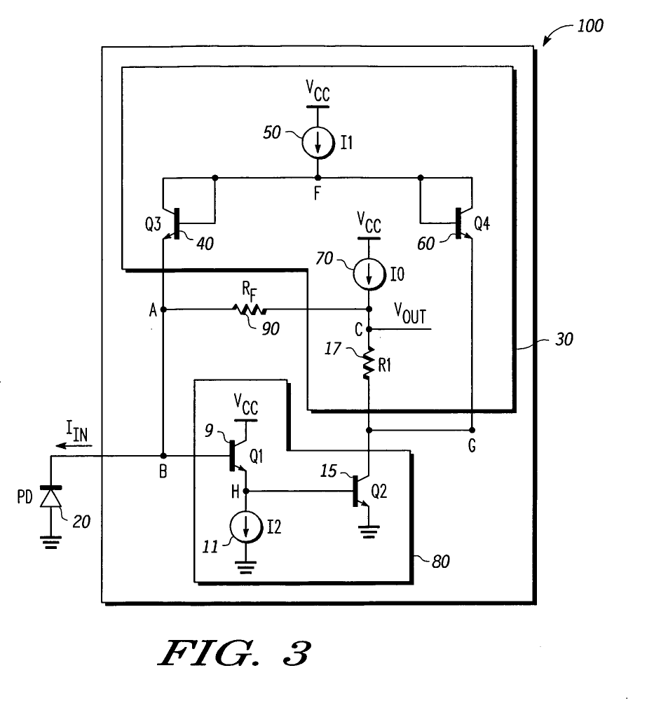

The following description refers to nodes or other features being “connected” or “coupled” together. As used herein, unless expressly stated otherwise, “connected” means that one node/feature is directly or indirectly connected to another node/feature, and not necessarily mechanically. Likewise, unless expressly stated otherwise, coupled means that one node/feature is directly or indirectly coupled to another node/feature, and not necessarily mechanically. Thus, although the schematics shown in FIG. 3 depicts exemplary arrangements of elements, additional intervening elements, devices, features, or components may be present in an actual embodiment (assuming that the functionality of the circuit is not adversely affected). Furthermore, the connecting lines shown in the various figures contained herein are intended to represent example functional relationships and/or physical couplings between the various elements. It should be noted that many alternative or additional functional relationships or physical connections may be present in a practical embodiment or implementation.

The embodiments described below can help to achieve a precise definition of the non-linear transimpedance of a limiting circuit. This precise definition helps reduce the variation in the swing or dynamic range of the output voltage (Vout). For instance, in one embodiment, the dynamic range of the output voltage (Vout) is 0.5 V or less. A smaller swing of the dynamic range of the output voltage (Vout) can allow a larger gain to be applied in the succeeding circuits coupled to the output of the transimpedance amplifier. In some implementations, the achievable signal-to-noise ratio (SNR) of the output voltage (Vout) can be improved by about 1.5 dB, and signal-to-offset ratio (SOR) of the output voltage (Vout) can be approved by about two times which enables sensitivity improvement of about 2 electrical dB. In one embodiment, the transimpedance amplifier can also generate a correct digital output voltage (Vout) signal in response to an incoming light signal having an optical power of −35 dBm.

FIG. 3 is a circuit diagram of an optical receiver module that includes a photodiode 20 and a transimpedance amplifier 100. The transimpedance amplifier 100 can include a limiting circuit 30, a transconductance amplifier 80, and a feedback resistor (Rf) 90. The photodiode (PD) 20 is coupled between node B and ground, the feedback resistor (Rf) is coupled between node A and node C, the transconductance amplifier 80 is coupled between node B and node G, and the limiting circuit 30 is coupled between node A and node G. It should be noted that node B can alternatively be grounded, or connected to ground via capacitor (not shown).

The photodiode (PD) 20 receives a light or optical signal from a fiber (not shown) and generates an input current (Iin) responsive to the light signal at node B.

The feeback resistor (Rf) 90 is coupled between the limiting circuit 30 and the photodiode (PD) 20.

In one embodiment, the transconductance amplifier 80 comprises a current source (I2) 11 coupled between node H and ground, a first transistor (Q1) 9 coupled between node B and node H and the power supply voltage (Vcc), and a second transistor (Q2) 15 coupled between nodes G and H and ground.

The current source (I2) 11 provides a bias current (I2) which is proportional-to-absolute-temperature (PTAT), and inversely proportional to on-chip resistances.

The first transistor (Q1) 9 comprises a third base, a third emitter, and a third collector. The third base is coupled to node B, the third emitter is coupled to node H, and the third collector is coupled to the power supply (Vcc). The second transistor (Q2) 15 comprises a fourth base, a fourth emitter, and a fourth collector. The fourth emitter is grounded, the fourth collector is coupled to the node G, and the fourth base is coupled to node H. The second transistor (Q2) 15 acts as a current source which creates a voltage drop across the resistor (R1).

In one embodiment, the limiting circuit 30 comprises a current source (I1) 50 coupled between a power supply (Vcc) and node F, a diode connected transistor (Q3) 40 coupled between node A and node F, a diode connected transistor (Q4) 60 coupled between node G and node F, current source (I0) 70 coupled between a power supply voltage (Vcc) and node C, and a resistor (R1) 17 coupled between node C and node G. The output voltage (Vout) is generated at node C.

The current source (I0) 70 and the current source (I1) 50 each provide a bias current which is proportional-to-absolute-temperature (PTAT), and inversely proportional to on-chip resistances.

The diode connected transistor (Q3) 40 comprises a first base, a first emitter, and a first collector. The first emitter is coupled to node A, and the first collector is coupled to the node F and the first base. The second diode connected transistor (Q4) 60 comprises a second base, a second emitter, and a second collector. The second emitter is coupled to node G, and the second collector is coupled to the node F and the second base. The diode connected transistor (Q3) 40 and the diode connected transistor (Q4) 60 are matched transistors. The resistor (R1) 17 and the second diode connected transistor (Q4) 60 are configured to pre-bias the first diode-connected transistor (Q3) 40.

The current source (I1) 50 provides a bias current (I1) which generates a base voltage at the first base and the second base. The base voltages are approximately equal to each other. As such, the difference between the base-to-emitter voltage (V_{be3}) and the base-to-emitter voltage (V_{be4}) depends on the difference between the emitter voltages at the first and second emitters.

The first diode-connected transistor (Q3) 40 functions as a “limiting device.” The diode connected transistor (Q3) 40 has an impedance (Z_{Q3}) associated therewith which decreases proportionately as the input current (Iin) increases. The impedance (Z_{Q3}) of diode connected transistor (Q3) 40 in parallel with feedback resistor (Rf) 90 forms the transimpedance of the transimpedance amplifier 100. This allows for a precise definition of the input current (Iin) at which limiting of the swing of the output voltage (Vout) effectively begins.

To reduce the swing of the output voltage (Vout), the limiting action of the first diode-connected transistor (Q3) 40 should start as early as possible. Yet, this limiting action should not be applied to minimum input current (Iin) for logic high situation since it would degrade SNR. Therefore, the limiting action should “kick-in” at a precisely defined value of the input current (Iin) which is somewhat above the minimum input current (Iin) for logic high. As will be explained below, the diode-connected transistor (Q3) 40 is pre-biased to a given base-to-emitter voltage (V_{be3}) and very small collector current (I_{c3}) when input current (Iin) is approximately zero. Pre-biasing the diode-connected transistor (Q3) 40 reduces the amount that the base-to-emitter voltage (V_{be3}) must change to begin limiting the swing of the output voltage (Vout). The diode connected transistor (Q3) 40 begins limiting the swing of the output voltage (Vout) when the input current (Iin) reaches a selected “knee” value of the input current (Iin) which is slightly above a minimum input current (Iin) for logic high. The selected “knee” value of the input current (Iin) can also be referred to as a “knee current (Ik).” An input current flow (Iin) between 375 nA to 320 μA corresponds to a logic high. The “knee” value of the input current (Iin) can be selected from a range of values of the input current (Iin) where the diode connected transistor (Q3) 40 begins limiting the swing of the output voltage (Vout). In one implementation, the range of the knee values is greater than or equal to five times the minimum input current (Iin) for logic high. In one embodiment, the diode connected transistor (Q3) 40 begins limiting the swing of the output voltage (Vout) when the impedance of the first diode connected transistor (Q3) 40 is greater than or equal to 10 times the value of feedback resistor (Rf) 90.

The operation of one embodiment of the transimpedance amplifier 100 will now be described with reference to FIG. 3 and equations (1) through (9).

For typical application temperature range of −40 C to +95 C the PTAT variation is:

$$\frac{95 ° C . + 273 ° C .}{- 40 + 273} = \frac{368 ° K .}{233 ° K .} = 1.58 \text{:} 1$$

A voltage-to-current characteristic of a bipolar junction transistor (BJT), such as diode connected transistor (Q3) 40 and diode connected transistor (Q4) 60, is shown in equation (1) below.

$${I}_{c} = {I}_{s} \cdot {ⅇ}^{\frac{{V}_{BE}}{{V}_{T}}} \qquad ( 1 )$$

In equation (1), I_{c} is the collector current (I_{c}), V_{BE} is the base-emitter voltage (V_{BE}), Iₛ is the reverse saturation current (Iₛ), and V_{T}=k*T/q is the ‘thermal’ voltage. The thermal voltage (V_{T}) is PTAT and depends on Boltzman constant (k), absolute temperature (T), and charge of the electron (q).

With low input current (Iin), almost the entire current from current source (I1) 50 flows through diode connected transistor (Q4) 60. Also, almost the entire current from current source (I0) 70 flows through resistor (R1) 17 and transistor (Q2) 15. The feedback resistor (Rf) 90 conducts the base current (Ib1) of first transistor (Q1) 9. In this situation, the base-to-emitter voltage (V_{be3}) of the diode-connected transistor (Q3) 40 can then be determined by summing the voltages around the loop which contains the diode connected transistor (Q3) 40, the diode connected transistor (Q4) 60, the resistor (R1) 17 and the feedback resistor (Rf) 90. The base-to-emitter voltage (V_{be3}) of the diode-connected transistor (Q3) 40 is shown below in equation (2).
V_{be3}=V_{be4}+Iᵢₙ·R_{f}−(I₀·R₁−I_{b1}·R_{f}) (2)

Resistors (R1) 17 and (Rf) 90 do not change appreciably with temperature. Thus, the terms I₀*R₁ and I_{b1}*R^{f} are PTAT, and the term in the parentheses of equation (2) is PTAT. The term in the parentheses of equation (2) is PTAT since the current source (I0) 70 is PTAT, and the base current (Ib1) of first transistor (Q1) 9 is a fraction of the current source (I2) 11 which is PTAT as well. The term in the parentheses of equation (2) can thus be referred to as the “PTAT voltage.”

To express the base-to-emitter voltage (V_{be3}) of the diode-connected transistor (Q3) 40 as a function of thermal voltage (V_{T}), a dimensionless number (X) can be defined as being equal to (I₀·R₁−I_{b1}·R_{f})/V_{T}. Defining the dimensionless number (X) provides a convenient way to relate the collector current (1_{c3}) of diode connected transistor (Q3) 40 to the collector current (I_{c4}) of diode connected transistor (Q4) 60. Hence, equation (2) can be written as equation (3) below.
V_{be3}=V_{be4}+Iᵢₙ·R_{f}−X·V_{T} (3)

Thus, the base-to-emitter voltage (V_{be3}) of the diode-connected transistor (Q3) 40 is equal to the sum of the base-to-emitter voltage (V_{be4}) of the diode-connected transistor (Q4) 60 and the product of the input current (Iin) and the feedback resistor (Rf) 90, minus the product of the dimensionless number (X) and the thermal voltage (V_{T}). The value of the dimensionless number (X) can be selected to precisely define the point at which the diode-connected transistor (Q3) 40 begins to limit the swing of the output voltage (Vout). The dimensionless number (X) is independent of temperature.

When the input current (Iin) is zero, the voltage across the feedback resistor (Rf) can be assumed negligible, and equation (3) becomes equation (4) below.
V_{be3}=V_{be4}−X·V_{T} (4)

In other words, when the input current (Iin) is zero, the base-to-emitter voltage (V_{be3}) of the diode-connected transistor (Q3) 40 is approximately equal to the base-to-emitter voltage (V_{be4}) of the diode-connected transistor (Q4) 60 minus the product of the dimensionless number (X) and the thermal voltage (V_{T}). In general, the collector current (I_{c3}) of diode connected transistor (Q3) 40 as a function of the input current (Iin) can be obtained by substituting equation (3) into equation (1) as shown in equation (5) below.

$${I}_{c 3} ( {I}_{i n} ) = {I}_{s} \cdot {ⅇ}^{\frac{{V}_{be 4} + {I}_{i n} \cdot {R}_{f} - X \cdot {V}_{T}}{{V}_{T}}} \\ or \\ \begin{matrix}{I}_{c 3} ( {I}_{i n} ) = {I}_{s} \cdot {ⅇ}^{\frac{{V}_{be 4}}{{V}_{T}}} \cdot {ⅇ}^{ \frac{ {I}_{ i n} \cdot {R}_{f}}{ {V}_{ T}}} \cdot {ⅇ}^{- X} \\ = {I}_{c 4} \cdot {ⅇ}^{ \frac{ {I}_{ i n} \cdot {R}_{f}}{ {V}_{ T}}} \cdot {ⅇ}^{- X}\end{matrix} \qquad ( 5 )$$

When the input current (Iin) is very small, the collector current (I_{c3}) of diode connected transistor (Q3) 40 is shown below in equation (6).

$$\begin{matrix}{I}_{c 3} ( 0 ) = {I}_{s} \cdot {ⅇ}^{\frac{{V}_{be 4} - X \cdot {V}_{T}}{{V}_{T}}} \\ = {I}_{s} \cdot {ⅇ}^{\frac{{V}_{be 4}}{{V}_{T}}} \cdot {ⅇ}^{- X} \\ = {I}_{c 4} \cdot {ⅇ}^{- X}\end{matrix} \qquad ( 6 )$$

Thus, when the input current (Iin) is very small such that it approaches zero, the collector current (I_{c3}(0)) of diode connected transistor (Q3) 40 is proportional to the collector current (I_{c4}) of diode connected transistor (Q4) 60. Since the collector current (I_{c4}) of diode connected transistor (Q4) 60 is PTAT, the collector current (I_{c3}(0)) of diode connected transistor (Q3) 40 at small input currents (Iin) is PTAT as well. The exact value of the dimensionless number (X) can be chosen such that the limiting action of diode connected transistor (Q3) 40 begins at a desired input current (Iin). Thus, by selecting an appropriate value for the dimensionless number (X), the diode connected transistor (Q3) 40 can be pre-biased to a precisely defined and very small current (I_{c3}).

### EXAMPLE

The overall input current (Iin)-to-output voltage (Vout) characteristic of the transimpedance amplifier 100 begins to change from linear to logarithmic at a “knee” current (Ik) when the input current (Iin) is safely larger than the minimum input current (Iin) for logic high. The impedance (Z_{Q3}) of diode connected transistor (Q3) 40 can be defined as shown in equation (7) below.

$${Z}_{Q 3} = \frac{1}{{g}_{m 3}} = \frac{{V}_{T}}{{I}_{C 3}} \qquad ( 7 )$$

The impedance (Z_{Q3}) of diode connected transistor (Q3) 40 is also equal to (V_{T}/I1)*exp(X) which is equal to the on chip resistance *exp(X). This relationship allows precise definition of the input current (Iin) at which limiting effectively begins.

As noted above, the impedance (Z_{Q3}) of diode connected transistor (Q3) 40 in parallel with feedback resistor (Rf) 90 forms the transimpedance of the transimpedance amplifier 100. The ratio of the impedance (Z_{Q3}) of diode connected transistor (Q3) 40 to the feedback resistor (Rf) 90 should be set such that the feedback resistor (Rf) 90 dominates the value of the transimpedance.

In this example, the value of the transimpedance can be set such that it is attributable to the feedback resistor (Rf) 90 by at least 90% or more. This way the transimpedance amplifier 100 can be designed such that limiting begins when the impedance (Z_{Q3}) of the diode connected transistor (Q3) 40 reaches a value ten times greater than the value of the feedback resistor (Rf) 90. By substituting equation (5) into equation (7), and replacing the input current (Iin) with the knee current (Ik), an expression shown in equation (8) below can be obtained.

$$X = \frac{{I}_{k} \cdot {R}_{f}}{{V}_{T}} + ln ( \frac{10 \cdot {R}_{f} {I}_{C 4}}{{V}_{T}} ) = 16.8 \qquad ( 8 )$$

In this example, the impedance (Z_{Q3}) of the diode connected transistor (Q3) 40 as a function of the input current (Iin) can therefore be expressed as equation (9) below.

$${Z}_{Q 3} ( {I}_{i n} ) = 10 \cdot {R}_{f} \cdot {ⅇ}^{\frac{- ( {I}_{i n} - {I}_{k} ) \cdot {R}_{f}}{{V}_{T}}} \qquad ( 9 )$$

Thus, the impedance (Z_{Q3}) of the diode connected transistor (Q3) 40 is very large for an input current (Iin) which is less than the knee current (Ik). For an input current (Iin) which is equal to the knee current (Ik), the impedance (Z_{Q3}) of the diode connected transistor (Q3) 40 is ten times the value of the feedback resistor (Rf) 90. For an input current (Iin) which is greater than the knee current (Ik), the impedance (Z_{Q3}) of the diode connected transistor (Q3) 40 reduces exponentially with input current (Iin).

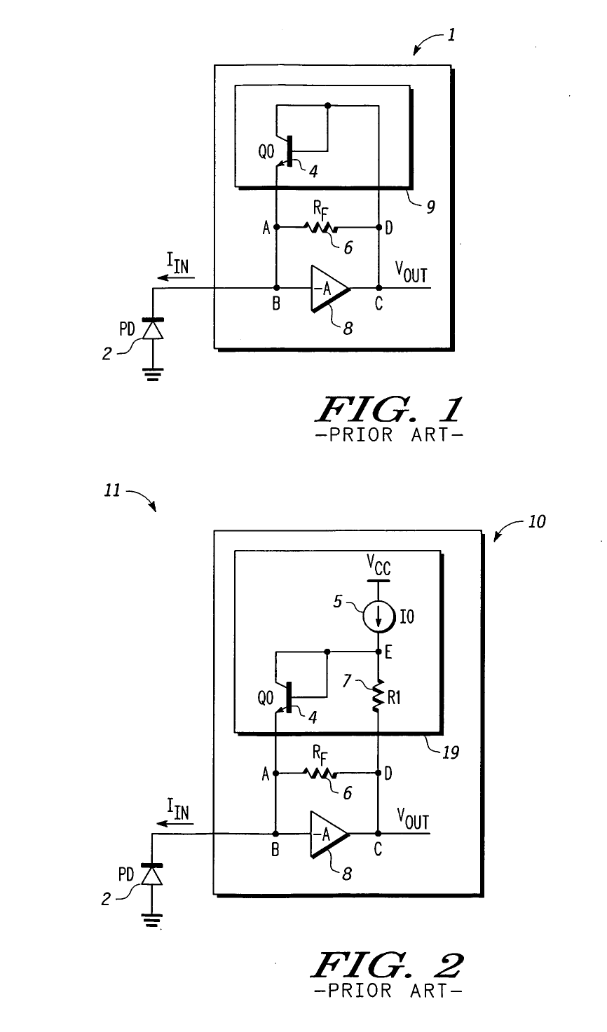

Accordingly, for a given value of X, the knee current (Ik) is PTAT since it varies only with the temperature. As noted above, this variation is 1.58:1 over the temperature range of typical application temperature range of −40 C to +95 C. Therefore, the precise beginning of the limiting action by diode connected transistor (Q3) 40 can be achieved. Since this action begins at small values of the input current (Iin), the swing of the output voltage (Vout) at maximum input current (Iin) can be reduced. The initial base-to-emitter voltage (V_{be3}) of the diode-connected transistor (Q3) 40 is larger than the initial base-to-emitter voltage (V_{be0}) of the diode-connected transistor (Q0) 4 shown in FIGS. 1 and 2. Consequently, the output voltage (Vout) has smaller overall dynamic range or swing which can be, for example, 0.50V under all conditions, in comparison to about 1V and 0.8V for circuits from FIGS. 1 and 2, respectively. In this particular example, the swing of the output voltage (Vout) at maximum input current (Iin) is 0.44V. As such, more gain can be applied to the output voltage (Vout) of the transimpedance amplifier 100. In this example, an additional gain of more than two can be applied to the output voltage (Vout) signal of the transimpedance amplifier 100 shown in FIG. 3.

According to one implementation a transimpedance amplifier can be provided which includes an input configured to provide an input current which includes a logic high range between a minimum input current for logic high and a maximum input current for logic high; an amplifier, coupled between a first node and a second node; and a non-linear limiting circuit, coupled between the first node and the second node. The non-linear limiting circuit may include, for example, a first current source, coupled between a power supply and a third node, configured to provide a first bias current proportional to absolute temperature, a second current source, coupled between the power supply and a fourth node, configured to provide a third bias current which is proportional to absolute temperature, a resistor coupled between the fourth node and the second node, wherein an output voltage is generated at the fourth node having a range between a first voltage and a second voltage; a first diode connected transistor comprising a first base coupled to the third node, a first emitter coupled to the first node, and a first collector coupled to the third node, wherein the first diode connected transistor is prebiased to generate a first base-to-emitter voltage when the input current is approximately zero, and a second diode connected transistor comprising a second base coupled to the third node, a second emitter coupled to second node, and a second collector coupled to the third node. The resistor and the second diode connected transistor can be configured to pre-bias the first diode-connected transistor.

According to one implementation, the first diode connected transistor is matched to the second diode connected transistor.

According to one implementation, the amplifier is coupled between first node and the fourth node, and further comprises a third current source coupled between fifth node and ground, wherein the third current source provides a third bias current which is proportional to absolute temperature; a first transistor comprising a third base coupled to first node, a third emitter coupled to a fifth node, and a third collector is coupled to the power supply; and a second transistor comprising a grounded fourth emitter, a fourth collector coupled to the second node, and a fourth base coupled to fifth node.

According to one implementation, the input current includes a range of knee values, and wherein the first diode connected transistor is configured to begin limiting the range of the output voltage at a selected one of the knee values which is slightly greater than the minimum input current for logic high. A first base-to-emitter voltage of the first diode connected transistor changes to begin limiting the range of the output voltage when the input current reaches the selected one of the knee values of the input current. An initial value of the first base-to-emitter voltage can determine the range of the output voltage. The range of the knee values may be greater than or equal to five times the minimum input current for logic high. According to one implementation, a feedback resistor can be coupled between the first node and the fourth node, and the first diode connected transistor has an impedance which decreases as the input current increases. The first diode connected transistor begins limiting the range of the output voltage when the impedance of the first diode connected transistor is greater than or equal to 10 times the value of feedback resistor. The feedback resistor can have a value greater than or equal to 80 kilo ohms. The impedance of the first diode connected transistor decreases exponentially with the input current if the input current is greater than the knee current. The first diode connected transistor is configured to begin limiting the range of the output voltage at a value of the input current which is defined based on a dimensionless number which is proportional to absolute temperature. The dimensionless number equals the difference between a first number and a second number divided by a thermal voltage, wherein the first number is the product of a current value of the second current source and the value of the resistor, and wherein the second number is the product of the value of the feedback resistor and a current value of a current flowing from the third base.

According to one implementation, a current of the first collector is proportional to a current from the second collector of when the input current approaches zero.

According to one implementation, the range of the output voltage is 0.5 volts or less at the maximum input current.

According to one implementation, the minimum input current for logic high is greater than or equal to 300 nA and the maximum input current for logic high is less than or equal to 320 μA. The input current of 375 nA to 320 μA is at least ten times greater than the input current flow which corresponds to logic low.

The tansimpedance amplifers described above may be utilized, for example, in an optical receiver which can be incorporated, for instance, into an optical module which includes a photodiode, coupled between a first node and ground, configured to receive a light signal and generate an input current responsive to the light signal, wherein the input current includes a logic high range between a minimum input current for logic high and a maximum input current for logic high.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A transimpedance amplifier, comprising:
an input configured to provide an input current which includes a logic high range between a minimum input current for logic high and a maximum input current for logic high;
an amplifier, coupled between a first node and a second node; and
a non-linear limiting circuit, coupled between the first node and the second node, comprising:
a first current source, coupled between a power supply and a third node, configured to provide a first bias current proportional to absolute temperature;
a second current source, coupled between the power supply and a fourth node, configured to provide a third bias current which is proportional to absolute temperature; and
a resistor coupled between the fourth node and the second node, wherein an output voltage is generated at the fourth node having a range between a first voltage and a second voltage;
a first diode connected transistor comprising a first base coupled to the third node, a first emitter coupled to the first node, and a first collector coupled to the third node, wherein the first diode connected transistor is prebiased to generate a first base-to-emitter voltage when the input current is approximately zero; and
a second diode connected transistor comprising a second base coupled to the third node, a second emitter coupled to second node, and a second collector coupled to the third node.

2. The transimpedance amplifier of claim 1, wherein the input current includes a range of knee values, and wherein the first diode connected transistor is configured to begin limiting the range of the output voltage at a selected one of the knee values which is slightly greater than the minimum input current for logic high.

3. The transimpedance amplifier of claim 2, wherein a first base-to-emitter voltage of the first diode connected transistor changes to begin limiting the range of the output voltage when the input current reaches the selected one of the knee values of the input current.

4. The transimpedance amplifier of claim 3, wherein an initial value of the first base-to-emitter voltage determines the range of the output voltage.

5. The transimpedance amplifier of claim 4, wherein the range of the knee values is greater than or equal to five times the minimum input current for logic high.

6. The transimpedance amplifier of claim 5, wherein the first diode connected transistor has an impedance which decreases as the input current increases, and further comprising:
a feedback resistor coupled between the first node and the fourth node,
wherein the first diode connected transistor begins limiting the range of the output voltage when the impedance of the first diode connected transistor is greater than or equal to 10 times the value of feedback resistor.

7. The transimpedance amplifier of claim 6, wherein the feedback resistor has a value greater than or equal to 80 kilo ohms.

8. The transimpedance amplifier of claim 6, wherein the impedance of the first diode connected transistor decreases exponentially with the input current if the input current is greater than the knee current.

9. The transimpedance amplifier of claim 2, wherein the first diode connected transistor is configured to begin limiting the range of the output voltage at a value of the input current which is defined based on a dimensionless number which is proportional to absolute temperature.

10. The transimpedance amplifier of claim 9, wherein the dimensionless number equals the difference between a first number and a second number divided by a thermal voltage, wherein the first number is the product of a current value of the second current source and the value of the resistor, and wherein the second number is the product of the value of the feedback resistor and a current value of a current flowing from the third base.

11. The transimpedance amplifier of claim 1, wherein a current of the first collector is proportional to a current from the second collector of when the input current approaches zero.

12. The transimpedance amplifier of claim 1, wherein the first diode connected transistor is matched to the second diode connected transistor.

13. The transimpedance amplifier of claim 12, wherein the resistor and the second diode connected transistor are configured to pre-bias the first diode-connected transistor.

14. The transimpedance amplifier of claim 1, wherein the amplifier is coupled between first node and the fourth node, and wherein the amplifier further comprises:
a third current source coupled between fifth node and ground, wherein the third current source provides a third bias current which is proportional to absolute temperature;
a first transistor comprising a third base coupled to first node, a third emitter coupled to a fifth node, and a third collector is coupled to the power supply; and
a second transistor comprising a grounded fourth emitter, a fourth collector coupled to the second node, and a fourth base coupled to fifth node.

15. The transimpedance amplifier of claim 1, wherein the range of the output voltage is 0.5 volts or less at the maximum input current.

16. The transimpedance amplifier of claim 1, wherein the minimum input current for logic high is greater than or equal to 300 nA and the maximum input current for logic high is less than or equal to 320 μA.

17. A transimpedance amplifier, comprising:
an input configured to provide an input current which includes a logic high range between a minimum input current for logic high and a maximum input current for logic high;
an amplifier; and
a non-linear limiting circuit, comprising:
a second current source; and
a resistor coupled having a node between the second current source and the amplifier, wherein an output voltage is generated at the node having a range between a first voltage and a second voltage;
a first diode connected transistor, wherein the first diode connected transistor is prebiased to generate a first base-to-emitter voltage when the input current is approximately zero; and
a second diode connected transistor coupled to the first diode connected transistor.

18. A transimpedance amplifier, comprising:
an input configured to provide an input current which includes a logic high range between a minimum input current for logic high and a maximum input current for logic high, wherein the minimum input current for logic high includes a range of knee values;
an amplifier; and
a non-linear limiting circuit, comprising:
a second current source; and
a resistor coupled having a node between the second current source and the amplifier, wherein an output voltage is generated at the node having a range between a first voltage and a second voltage;
a first diode connected transistor, wherein the first diode connected transistor is prebiased to generate a first base-to-emitter voltage when the input current is approximately zero, wherein the first diode connected transistor is configured to begin limiting the range of the output voltage at a selected one of the knee values which is slightly greater than the minimum input current for logic high; and
a second diode connected transistor coupled to the first diode connected transistor, wherein the resistor and the second diode connected transistor are configured to pre-bias the first diode-connected transistor.

19. The transimpedance amplifier of claim 18, wherein a first base-to-emitter voltage of the first diode connected transistor changes to begin limiting the range of the output voltage when the input current reaches the selected one of the knee values of the input current.

20. The transimpedance amplifier of claim 19, wherein the first diode connected transistor is matched to the second diode connected transistor.

21. An optical receiver, comprising:
a transimpeadance amplifier as claimed in claim 1.

22. An optical module, comprising:
a photodiode, coupled between a first node and ground, configured to receive a light signal and generate an input current responsive to the light signal, wherein the input current includes a logic high range between a minimum input current for logic high and a maximum input current for logic high; and
a transimpedance amplifier as claimed in claim 1, the transimpedance amplifier including the first node.
